(19) United States
(12) Patent Application Publication
(10) Pub. No.: US 2025/0323162 A1
(43) Pub. Date: Oct. 16, 2025

(54) Power Delivery Systems and Methods with a Single Power Rail

(71) Applicant: Altera Corporation, San Jose, CA (US)

(72) Inventors: Krishna Bharath Kolluru, Hillsboro, OR (US); MD Altaf Hossain, Portland, OR (US)

(21) Appl. No.: 19/251,122

(22) Filed: Jun. 26, 2025

(51) Int. Cl. H01L 23/528; H01L 23/00; H01L 23/538; H01L 25/065

(52) U.S. Cl. CPC H01L 23/5286; H01L 25/0652; H01L 25/0657; H01L 23/538; H01L 24/16; H01L 2224/16145; H01L 2224/16225; H01L 2225/06513; H01L 2225/06517; H01L 2924/1427

(57) ABSTRACT

Systems or methods of the present disclosure may relate to integrated circuits, such field-programmable gate arrays (FPGAs). The present disclosure includes an integrated circuit including one or more sectors of programmable logic circuitry, one or more I/O blocks respectively positioned proximate to the one or more sectors of programmable logic circuitry, and one or more voltage regulators. Each I/O block of the one or more I/O blocks includes a voltage regulator of the one or more voltage regulators. The voltage regulator may include one or more regulator phases that adjust voltage from a single power rail to a voltage level usable by the component. For example, the voltage regulator may turn on or off any suitable number of regulator phases to adjust the voltage to a suitable voltage level.

### BACKGROUND

The present disclosure relates generally to integrated circuits, such as field-programmable gate arrays (FPGAs). More particularly, the present disclosure relates to implementing voltage regulator circuitry within components (e.g., inputs/outputs (I/Os) blocks, programmable logic regions, and/or cores) of an integrated circuit device such as an FPGA.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuit devices are used for a variety of purposes or applications. Some integrated circuit devices, such as some processors, may include voltage regulators that provide power to one or more processor cores of the processor. In contrast, some integrated circuit devices may have such dense data routing that this has been infeasible. Programmable logic devices, a class of integrated circuit devices, may include voltage regulators positioned outside of and/or adjacent to the programmable logic devices due to routing density within the programmable logic device. However, placing the voltage regulators on a package substrate and communicatively coupling the voltage regulators to the programmable logic devices increases a distance between components of the programmable logic devices and the voltage regulators, which may result in inefficient power delivery to the components. Additionally, the programmable logic devices may receive power from multiple different power rails due to varying voltage levels used by different components, such as input/output (I/O) blocks, hardened processor systems (HPS), hardened accelerators, and/or programmable logic regions of the programmable logic devices. In some configurations, an integrated circuit device may include on-board voltage regulator circuitry, such as multiple different power rails, in order to provide voltage at the different target voltage levels usable by the different components. As such, a number of power rails used to adjust the voltage may increase. However, increasing the number of power rails may also increase a number of ball grid array (BGA) balls used to deliver the power to the power rails may also increase, which may result in a bigger package size.

### BRIEF DESCRIPTION OF THE DRAWINGS

Various aspects of this disclosure may be better understood upon reading the following detailed description and upon reference to the drawings in which:

FIG. 1 is a block diagram of a system used to program a system design onto an integrated circuit system, in accordance with an embodiment of the present disclosure;

FIG. 2 is a block diagram of an example integrated circuit system of FIG. 1, in accordance with an embodiment of the present disclosure;

FIG. 3 is a block diagram of an embodiment of the integrated circuit system of FIG. 1 including voltage regulator circuitry positioned within an integrated circuit system of FIG. 1, in accordance with an embodiment of the present disclosure;

FIG. 4 is a block diagram of an example topology of an integrated circuit within the integrated circuit system of FIG. 1, in accordance with an embodiment of the present disclosure;

FIG. 5 is a flowchart of a method for manufacturing the integrated circuit system of FIG. 1, in accordance with an embodiment of the present disclosure; and

FIG. 6 is a block diagram of a data processing system including the integrated circuit system of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

The present disclosure is related to systems and techniques related to implementing voltage regulators (e.g., voltage regulator circuitry) within different components (e.g., input/output (I/O) blocks, programmable logic regions, cores of integrated circuits to improve power delivery and form factor. The cores may include functional blocks such as memory blocks, digital signal processing (DSP) blocks, adaptive logic modules (ALMs), logic elements, and so on. For example, the embodiments described herein are directed to a single power rail that provides power to the voltage regulator disposed within the I/O blocks, programmable logic regions, and/or cores of the integrated circuit. That is, each I/O block, programmable logic block, and/or core of the integrated circuit may include an instance of voltage regulator to adjust a received voltage (e.g., power) to a target voltage level usable by the I/O block, programmable logic block, and/or core, respectively. By implementing voltage regulator that provides power at a target level usable by the component, a number of power rails may be reduced, thereby reducing a number of BGA balls and the package size. This power delivery scheme may also reduce a bill of materials (BOM) cost by using die side capacitors (DSCs) and/or Land Side Capacitors (LSC) from a package substrate, reduce a number of substrate layers used for power delivery, and/or reduce a size of the integrated circuit system. Additionally or alternatively, using a single power rail at higher voltage levels may reduce an amount of current used by the integrated circuit system, thereby reducing IR drop losses. In this way, the single power rail may simplify the power delivery scheme implemented by the integrated circuit system and improve power delivery operations.

For example, the embodiments described herein implement a simplified power delivery scheme for integrated circuit systems with 2-dimensional (2D), 2.5-dimensional (2.5D), and/or 3-dimensional (3D) architectures (e.g., forms, configurations), where a single input power rail may provide voltage (e.g., power) to voltage regulators positioned within components of the integrated circuit. A Printed Circuit Board (PCB) Voltage Regulator (VR) may provide single input voltage to power delivery circuitry (e.g., voltage regulator circuitry). The output connection between the PCB VR and the voltage regulators disposed within the I/O blocks may be different based on implementation. The implementation may include a capacitor-based implementation or inductor-based implementation. For example, with the capacitor-based solution, power may be delivered by a voltage rail (e.g., the single power rail) of the PCB. The power may flow through package balls coupled to the PCB and then to an integrated circuit of the integrated circuit system. The integrated circuit may receive a voltage level greater than 1.6 Volts (V) and adjust the voltage, via one or more voltage regulators, to many different voltage levels usable by different components of the integrated circuit. In another example, with the inductor-based solution, the power may be delivered by a voltage input from PCB VR to a package substrate (and/or the single power rail) and inductor within the package substrate. The power may be provided to an integrated circuit of the integrated circuit system at a voltage level less than or equal to 1.6 V. The voltage regulators within the integrated circuit may receive the voltage and adjust the voltage to different voltage levels usable by different components of the integrated circuit. As discussed herein, the integrated circuit may include individual instances of voltage regulators within the components, and the voltage regulator may adjust the voltage to a target voltage level usable by the component. By way of specific example, the voltage regulator positioned within a programmable input/output (I/O) block, and the voltage regulator may step down the voltage provided by the input power rail (e.g., single power rail) to a target voltage level usable by the I/O block. The components may include programmable I/O blocks (e.g., general purpose input/output (GPIO) block for double-data rate (DDR) or low-voltage differential signaling (LVDS)) for various high current load applications.

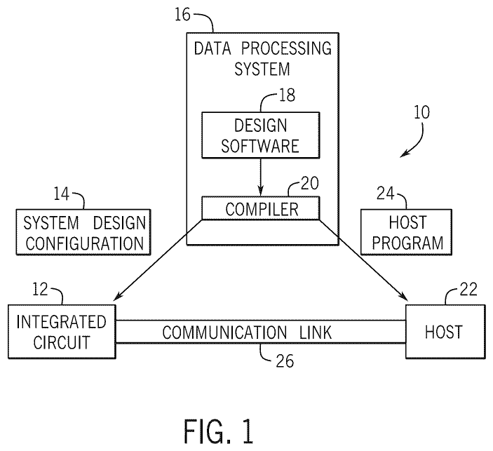

With the foregoing in mind, FIG. 1 illustrates a block diagram of a system 10 that may be used to program an integrated circuit device 12, such as a field-programmable gate array (FPGA) (e.g., Agilex™, Stratix®, Arria®, MAX®, or Cyclone® devices by Altera® Corporation), with a system design using a system design configuration 14. Note that, while this disclosure largely refers to the integrated circuit device 12 as being a programmable logic device, such as an FPGA, in some embodiments, the integrated circuit device 12 may also be a one-time programmable device or structured application specific integrated circuit (ASIC), such as an Intel® eASIC™ device by Intel® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit device 12.

Additionally or alternatively, the host 22 running a host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

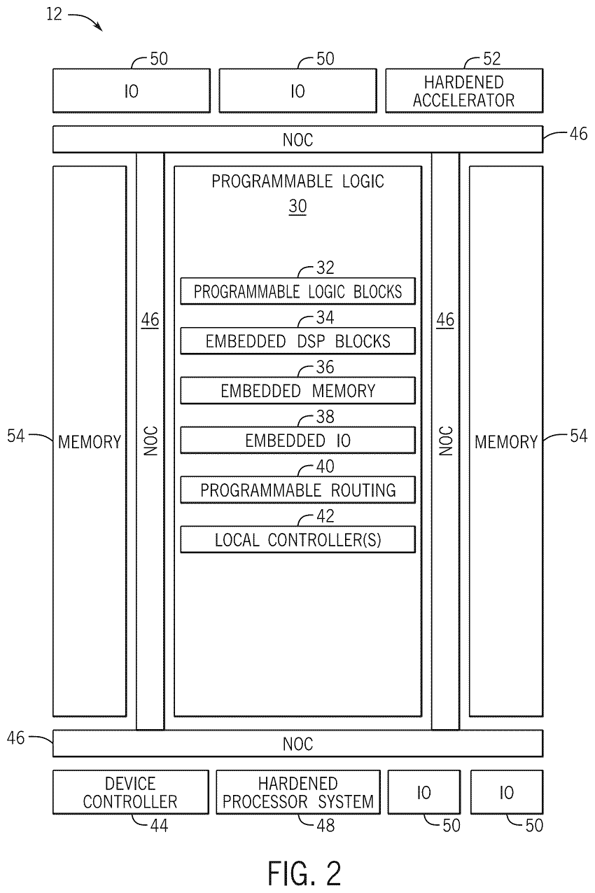

The integrated circuit device 12 may take any suitable form that may implement the system design configuration 14. In one example shown in FIG. 2, the integrated circuit device 12 may include programmable logic circuitry 30, which include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any of the programmable logic blocks 32 to implement any desired logic circuitry when configured with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 kB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit device 12. The device controller 44 may include any suitable logic circuitry to control and/or program the programmable logic circuitry 30 or other elements of the integrated circuit device 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit device 12.

A network-on-chip (NOC) 46 may connect the various elements of the integrated circuit device 12. The NOC 46 may provide rapid, packetized communication to and from the programmable logic circuitry 30 and other blocks, such as a hardened processor system 48, input/output (I/O) blocks 50, a hardened accelerator 52, and local device memory 54. The integrated circuit device 12 may include the hardened processor system 48 when the integrated circuit device 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The I/O blocks 50 may enable communication using any suitable communication protocol(s) with other devices outside of the integrated circuit device 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

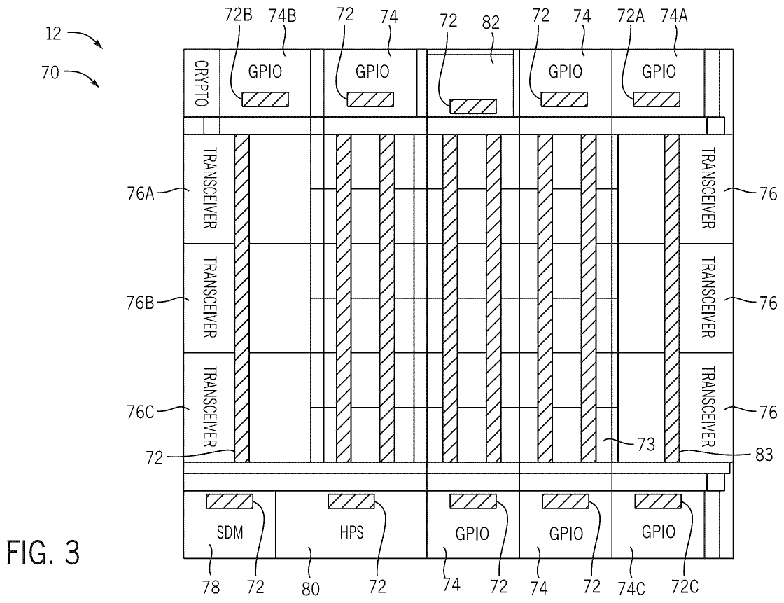

FIG. 3 is a schematic diagram of a topology implemented on the integrated circuit system 12 of FIG. 1 including a single power rail for power delivery. The integrated circuit system 12 may include an integrated circuit 70 with voltage regulators 72 (e.g., voltage regulator circuitry) positioned with different components of the integrated circuit 70. As illustrated, the integrated circuit 70 may include programmable logic regions 73 (e.g., programmable logic sectors, programmable logic circuitry), General Purpose I/O (GPIO) blocks 74 (e.g., programmable I/O blocks), transceiver blocks 76, a SDM 78, a hardened processor system (HPS) 80, and/or an encryption block 82. The GPIO blocks 74 may include any suitable programmable I/O block. For example, the programmable I/O blocks may support various high current load applications. It should be understood that the integrated circuit 70 may include fewer or more components than illustrated. For example, the integrated circuit 70 may include different types of I/O blocks, such as high-speed I/O blocks, on-package I/O blocks, and so on. As illustrated, the GPIO blocks 74, transceiver blocks 76, SDM 78, HPS 80, and the encryption block 82 may be positioned at the perimeter of the integrated circuit 70 and the programmable logic regions 73 may be positioned to these components.

The voltage regulators 72 may be distributed within the components of the integrated circuit 70. That is, each component may include a respective instance of the voltage regulator 72. Distributing the voltage regulators 78 among the components may provide for an electromigration and current voltage drop (EMIR) within a threshold EMIR. The voltage regulators 72 may receive input voltage in based on a number of regulator phases and adjust the outputted voltage based on a configured interface, which may utilize on-die circuitry to improve power delivery. For example, the voltage regulator 72 may receive more voltage when more regulator phases are turned on in comparison to when fewer regulator phases are turned on. The voltage regulator 72 may adjust the number of regulator phases that may be turned on based on request from the component and/or a state of the component. For example, the component may include a configured interface, such as the I/O blocks discussed herein. The I/O blocks may include parameters and/or settings to facilitate communication between different integrated circuits and/or different packages. The parameters and/or settings of the I/O blocks may include voltage levels to power the communication, and the parameters and/or settings may change based on changes to the type of communication, bandwidth utilization, and so on. That is, as the configuration of the I/O block changes, the amount of voltage used by the I/O block may also change. If the component requests more current than provided by the voltage regulator 72, the voltage regulator 72 may turn on more phases to receive more current from the single power rail. If the component requests less current, the voltage regulator 72 may turn off a number of phases to reduce power consumption. Therefore, the voltage regulators 72 may adjust current based on requests from the component and/or a configuration of the component (e.g., based on the configured interface). In certain embodiments, the voltage regulator 72 may receive a state of the component from the data processing system 16, such as after implementing a system design configuration 14 onto the integrated circuit system 12, after reconfiguring the integrated circuit system 12, after a partial reconfiguration of the integrated circuit system 12, and so on. In other embodiments, the I/O block may provide an indication of the voltage level used to facilitate communications. In certain embodiments, the voltage regulators 72 may implement power management and smartVID protocol techniques to support various I/O voltages. Utilizing on-die circuitry for power delivery may result in fewer components positioned on the motherboard (e.g., package substrate), which may reduce a total number of components used in the integrated circuit system 70. Additionally, reducing a number of components within the motherboard may reduce the board cost, increase area on the printed circuit board for additional components, and/or reduce a size of the integrated circuit.

As illustrated, the GPIO blocks 74 may each include a voltage regulator 72 disposed within the block, the SDM 78 may include a voltage regulator 72 disposed within the block, the HPS 80 may include a voltage regulator 72 disposed within the block, and the encryption block 80 may include a voltage regulator 82 disposed within the block. The single voltage regulator 72 within the GPIO blocks 74, the SDM 78, the HPS 80, and/or the encryption block 82 may receive voltage from the single power rail and adjust the voltage to voltage level usable by the respective component. In particular, the voltage regulator 72 may step down a voltage to a target voltage level usable by the component. In certain embodiments, the voltage regulator 72 may step up the voltage to the target voltage level.

With specific reference to the GPIO blocks 74, the GPIO blocks 74 may support many different I/O standards and/or protocols. The GPIO blocks may support communication with double data rate devices, such as DDR4, DDR5, and different protocols and/or standards, such as low-voltage differential signaling (LVDS), and the like. For example, a first GPIO block 74A may support a DDR5 device, and the first voltage regulator 72A disposed within the first GPIO block 74A may generate a first voltage usable by the DDR5 device. In another example, a second GPIO block 74B may support LVDS, and the second voltage regulator 72B disposed within the second GPIO block 74B may generate a second voltage usable for LVDS. The first voltage and the second voltage generated by the first voltage regulator 72A and the second voltage regulator 72B may be different. As such, the voltage regulators 72 may operate independently. Moreover, the voltage regulators 72 may be configurable to generate and/or adjust the voltage to the target voltage level usable by the component.

In another example, a third GPIO block 74C may not be supporting communication. As such, a third voltage regulator 72C disposed within the third GPIO block 74C may not draw power from the single power rail and may not provide power to the third GPIO block 74C, which may reduce overall power consumption by the integrated circuit 70.

Still in another example, the SDM 78 may operate using a fourth voltage, the HPS 80 may operate using a fifth voltage, and the encryption block 82 may operate using a sixth voltage. In an embodiment, the voltages may be different. In other embodiments, the voltages may be the same. Regardless, the voltage regulators 72 disposed within the different blocks may generate a voltage at a target voltage level usable by the blocks to perform respective operations. As such, the voltage regulators 72 may operate independently, which may increase flexibility within the integrated circuit 70.

In certain instances, one voltage regulator may provide power to two different components. The two components may use the same and/or similar voltage levels. For example, the transceiver blocks 76 may implement the same protocol and/or standard and thus may use the same voltage level. The transceiver blocks 76 may receive voltage from the same voltage regulator 72. As illustrated for example, a first transceiver block 76A, a second transceiver block 76B, and a third transceiver block 76C may receive voltage from a fourth voltage regulator 72D communicatively coupled to the three transceiver blocks 76A-C. The number of components supported by a voltage regulator 72 may be adjustable. For example, one voltage regulator 72 may provide power to two components, three components, four components, and so on. The number of components supported by the voltage regulators 72 may be determined based on the power requirements of the component and/or the target voltage levels usable by the component. As illustrated, each voltage regulator 72 may appear identical in shape and/or size, however, it should be noted that each voltage regulator 72 may be unique. That is, each voltage regulator 72 may include any suitable shape, size, and/or functionality (e.g., adjusting the voltage to different target voltage levels). Additionally or alternatively, the components may include more than one voltage regulator 72. For example, the GPIO block 74 may include two voltage regulators 72, three voltage regulators 72, or any suitable number of voltage regulators 72.

In certain instances, if a GPIO block 74 may be malfunctioning and/or not operational, then a voltage regulator 72 disposed within the GPIO block 74 may generate a current voltage based on a state (e.g., operational, malfunctioning) of the GPIO block 74. The GPIO block 74 may consume more voltage when malfunctioning than when the GPIO block 74 may be operational. The voltage regulator 72 within the GPIO block 74 may receive an indication to output higher voltage levels based on the GPIO block 74 malfunctioning. The GPIO block 74 may malfunction due to low operating voltage, therefore a higher voltage may help the GPIO block 74 pass data. It should be understood that any voltage regulator 72 disposed within any component may receive an indication to adjust voltage levels based on a state of the component. Additionally, the components may be programmable and/or re-programmable to perform different functions. For example, the first GPIO block 74A may be programmed to support DDR4 and then programmed to support DDR5, and so on. After being reprogrammed, the GPIO block 74A may use and/or provide a different target voltage level. In such case, the first voltage regulator 74A may be programmed and/or reprogrammed such that the first voltage regulator 72A provides a voltage at a target voltage level of the first GPIO block 74A.

As discussed herein, the integrated circuit 70 may include a single power rail that distributes power to each of the voltage regulators 72. Utilizing a single power rail may reduce a number of materials (e.g., the number of materials in the BOM) and/or components within the integrated circuit 70. For example, the integrated circuit 70 may include a single mother-board voltage regulator to provide the power, which may be a significant reduction in the number of mother-board voltage regulators in comparison to traditional configurations that may include multiple mother-board voltage regulators. Reducing the number of components within the integrated circuit 70 may simplify board logic, decrease a size of the integrated circuit 70 and/or increase space within the integrated circuit for other components, and power delivery operations. For example, the voltage regulators 72 may be individually controlled to output target voltages usable by the component.

The methods and techniques described in FIG. 3 may reduce a number of BGA balls used in power delivery, therefore providing for an integrated circuit 70 with a smaller form factor in comparison to traditional configurations. The integrated circuit 70 described with respect to FIG. 3 may use a signal integrity power integrity (SIPI) due to a reduced inductance loop, which improve overall power delivery within the integrated circuit system 12.

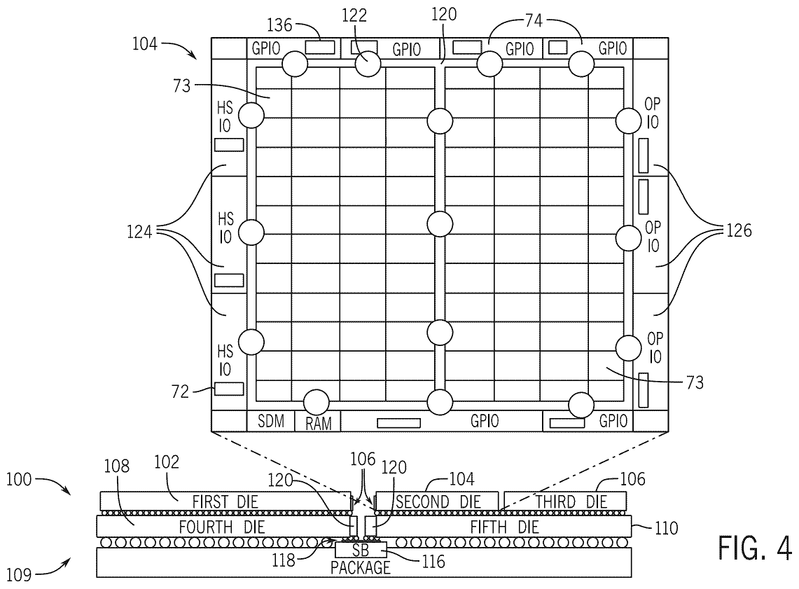

With the foregoing in mind, the integrated circuit 70 described with respect to FIG. 3 may be implemented in multi-die package 100 including multiple integrated circuits. One example of the integrated circuit device 12 as a multi-die package is illustrated in FIG. 4, but many others are described, and it should be understood that this disclosure is intended to encompass any suitable integrated circuit device 12. In the example of FIG. 4, the multi-die package 100 includes a first die 102, a second die 104, and/or a third die 106. The first die 102 may be mounted onto a fourth die 108 via microbumps 109. The second die 102 and the third die 104 may be mounted onto a fifth die 110 via microbumps 109. The first, second, and third dies 102, 104, 106 may be referred to herein as “top dies,” and the fourth and fifth dies 108, 110 may be referred to herein as “base dies.” Although the top dies and base dies appear in a one-to-one relationship or a two-to-one relationship in FIG. 4, other relationships may be used. For example, a single base die may attach to several top die, or several base die may attach to a single top die, or several base die may attach to several top die (e.g., in an interleaved pattern along the x- and/or y-direction). In the example of FIG. 4, two pairs of top die and base die are shown communicatively connected to one another via a silicon bridge 112 (e.g., an embedded multi-die interconnect bridge (EMIB)) and microbumps 114 at a silicon bridge interface 116.

For example, FIG. 4 illustrates a schematic diagram of a topology of the second die 104. However, it should be understood that the topology may be implemented on any suitable die. As illustrated, the second die 104 includes a network-on-chip (NOC) 120 that enables intra-die and inter-die communication, for example, via nodes 122, which may function as routers. In some embodiments, the nodes 124 may include protocol translators, which may convert the data formats, data rates, and/or and protocols of the NOC 122 into those associated with the programmable I/O blocks and/or cores or vice versa.

Additionally, the second die 104 may include the programmable logic blocks 73, which may be partial reconfiguration regions of the programmable logic elements of the second die 104 that may be modified (i.e., partially reconfigured) to implement new logic. Although not illustrated, the programmable logic blocks 73 may include a voltage regulator 72 disposed within each block 73 and/or a voltage regulator 72 disposed within a programmable logic block 73 and providing voltage to two or more programmable logic blocks 73. As such, the voltage regulators 72 may be distributed across the different programmable logic blocks 73.

FIG. 4 also depicts various types of programmable I/O blocks and/or cores that may be included in the second die 104. For example, as illustrated, the programmable I/O blocks may include high-speed input-outputs (HSIOs) 124, on-package IOs (OPIOs) 126, and GPIOs 74. As discussed herein, each programmable I/O block may include an instance of a voltage regulator 72 that outputs voltage at a target voltage usable by the respective I/O block. The voltage regulators 72 may receive voltage from a single power rail, adjust the voltage to a target voltage level, and output the voltage at the target voltage level to the component.

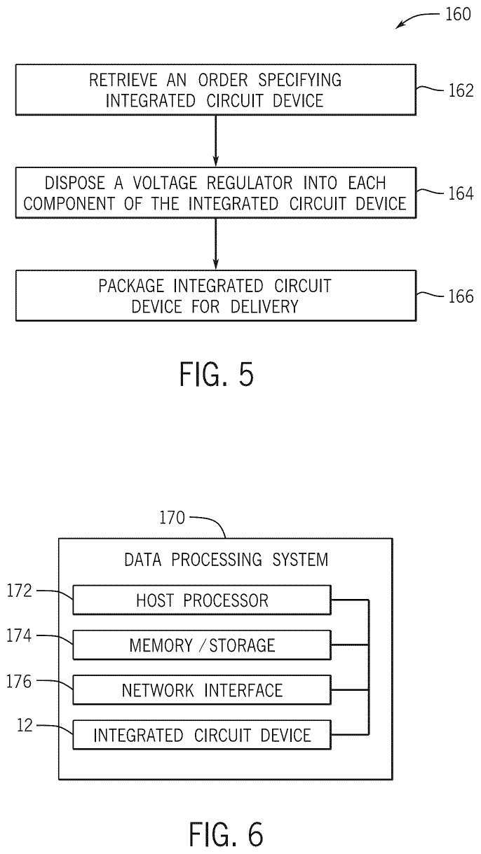

FIG. 5 is a flowchart of a method 160 for manufacturing the integrated circuit device 12 of FIG. 1. For example, a manufacturer may receive an order specifying the integrated circuit device 12 (block 162). The order may include a design for the integrated circuit device 12, including a number of integrated circuits, a number and/or a type of component within each integrated circuit, a number of voltage regulators 72, a number of voltage regulators 72 disposed within a component of the integrated circuits, a target voltage level of the component, a voltage domain for the component, a design to be implemented on the integrated circuit, and so on.

Based on the order, the manufacturer may dispose one or more voltage regulators into a component of the integrated circuit device (block 164). For example, a first voltage regulator may be positioned within a first component of the integrated circuit, a second voltage regulator may be positioned within a second component of the integrated circuit, and a third voltage regulator may be positioned with a third component of the integrated circuit. The first, second, and third voltage regulators may be coupled to a single power rail to receive a voltage. As such, the voltage regulators may be distributed across the integrated circuit.

The integrated circuit device 12 may be packaged for delivery (block 166). For example, the integrated circuit device 12 may be assembled by mounting one or more integrated circuits onto a package substrate and coupling the voltage regulators to a single power rail. The power fail may be disposed within the package substrate. The BOM associated with the integrated circuit device 12 may include fewer components in comparison to traditional configurations since power rails and/or voltage regulators included in the package substrate, in traditional configurations, may be migrated into the integrated circuit. That is, the voltage regulators may be formed by silicon within the integrated circuits rather than formed in the package substrate. This may provide a scalable and cost-efficient power dissipation across a range of products.

The method 160 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 160 may be performed by separate systems or devices.

The integrated circuit device 12 discussed above may be a component included in a data processing system, such as a data processing system 170, shown in FIG. 6. The data processing system 170 may include the integrated circuit device 12 (e.g., a programmable logic device, an application specific integrated circuit (ASIC)), a host processor 172, memory and/or storage circuitry 174, and a network interface 176. The data processing system 170 may include more or fewer components (e.g., electronic display, user interface structures, application specific integrated circuits (ASICs)). The host processor 172 may include any of the foregoing processors that may manage a data processing request for the data processing system 170 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 174 may include random access memory (RAM), read-only memory (ROM), one or more hard drives, flash memory, or the like. The memory and/or storage circuitry 174 may hold data to be processed by the data processing system 170. In some cases, the memory and/or storage circuitry 174 may also store configuration programs (e.g., bitstreams) for programming the integrated circuit device 12. The network interface 176 may allow the data processing system 170 to communicate with other electronic devices. The data processing system 170 may include several different packages or may be contained within a single package on a single package substrate. For example, components of the data processing system 170 may be located on several different packages at one location (e.g., a data center) or multiple locations. In some embodiments, components of the data processing system 170 may be located in separate geographic locations or areas, such as cities, states, or countries.

The data processing system 170 may be part of a data center that processes a variety of different requests. For example, the data processing system 170 may receive a data processing request via the network interface 176 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. An integrated circuit, including a plurality of sectors of programmable logic circuitry, a plurality of input/output (I/O) blocks respectively positioned proximate to the plurality of sectors of programmable logic circuitry, and a plurality of voltage regulators, wherein respective I/O blocks of the plurality of I/O blocks include a respective voltage regulator of the plurality of voltage regulators, and wherein the respective voltage regulators are configured to control a regulator phase of a plurality of regulator phases of the respective voltage regulator to operate based on a configuration of a respective component of circuitry of the plurality of I/O blocks and output a voltage to the respective component based on the regulator phase.

EXAMPLE EMBODIMENT 2. The integrated circuit of example embodiment 1, including one power rail communicatively coupled to the plurality of voltage regulators.

EXAMPLE EMBODIMENT 3. The integrated circuit of example embodiment 2, wherein each voltage regulator of the plurality of voltage regulators is to receive a voltage only from the one power rail, adjust the voltage to a target voltage level usable by a respective I/O block, and output the voltage at the target voltage level to the respective I/O block.

EXAMPLE EMBODIMENT 4. The integrated circuit of example embodiment 1, wherein a first I/O block of the plurality of I/O blocks is to support a first device operating at a first target level and a second I/O block of the plurality of I/O blocks is to support a second device operating at a second target level.

EXAMPLE EMBODIMENT 5. The integrated circuit of example embodiment 4, wherein the first I/O block includes a first voltage regulator of the plurality of voltage regulators and the second I/O block includes a second voltage regulator of the plurality of voltage regulators, wherein the first I/O block is to output a first voltage at a first target voltage level and the second voltage regulator is to output a second voltage at a second target voltage level different from the first target voltage level.

EXAMPLE EMBODIMENT 6. The integrated circuit of example embodiment 1, including a plurality of additional voltage regulators, wherein the plurality of additional voltage regulators is to provide a voltage to the plurality of sectors of programmable logic circuitry.

EXAMPLE EMBODIMENT 7. The integrated circuit of example embodiment 6, wherein a first additional voltage regulator of the plurality of additional voltage regulators is to provide a voltage to a first sector of the plurality of sectors of programmable logic circuitry and a second sector of the plurality of sectors of programmable logic circuitry.

EXAMPLE EMBODIMENT 8. The integrated circuit of example embodiment 1, wherein the respective voltage regulator is configured to receive an indication of an additional configuration of the respective component, control at least one regulator phase of the plurality of regulator phases to adjust operation based on the indication, and output an increased voltage to the respective component based on the at least one regulator phase, wherein the additional voltage is different from the voltage.

EXAMPLE EMBODIMENT 9. An integrated circuit, including one power rail to provide a voltage and a first voltage regulator coupled to the one power rail to receive the voltage, control a first regulator phase of a first plurality of regulator phases of the first voltage regulator to operate, adjust, via the first regulator phase, the voltage to a first voltage level usable by a first I/O block of a plurality of I/O blocks to support communications using a first protocol, and provide the first voltage level to the first I/O block based on a configuration of the first I/O block, wherein the first voltage regulator is disposed within the first I/O block.

EXAMPLE EMBODIMENT 10. The integrated circuit of example embodiment 9, including a second voltage regulator coupled to the one power rail, the second voltage regulator to receive the voltage, control a second regulator phase of a second plurality of regulator phases of the second voltage regulator to operate, adjust, via the second regulator phase, the voltage to a second voltage level usable by a second I/O block of a plurality of I/O blocks to support communications using a second protocol, and provide the voltage to the second I/O block based on a configuration of the second I/O block, wherein the second voltage regulator is disposed within the second I/O block.

EXAMPLE EMBODIMENT 11. The integrated circuit of example embodiment 10, wherein the first voltage level and the second voltage level are different.

EXAMPLE EMBODIMENT 12. The integrated circuit of example embodiment 10, and wherein the first voltage level and the second voltage level are the same.

EXAMPLE EMBODIMENT 13. The integrated circuit of example embodiment 9, wherein the first I/O block is to support communications using the first protocol and configurable to support communications using a second protocol different from the first protocol, and wherein the first voltage regulator is configurable to provide voltage at a second voltage level usable by the first I/O block when supporting the communications using the second protocol.

EXAMPLE EMBODIMENT 14. The integrated circuit of example embodiment 9, wherein the first I/O block includes programmable I/O blocks.

EXAMPLE EMBODIMENT 15. The integrated circuit of example embodiment 9, wherein the first voltage regulator is to provide the first voltage level to a second I/O block of the plurality of I/O blocks.

EXAMPLE EMBODIMENT 16. A multi-die package, including a first integrated circuit including a first plurality of input/output (I/O) blocks and a first plurality of voltage regulators, wherein respective I/O blocks of the first plurality of I/O blocks include a voltage regulator of the first plurality of voltage regulators, and wherein each voltage regulator of the first plurality of voltage regulators is configured to control a regulator phase of a plurality of regulatory phases of each voltage regulator to operate based on a configuration of a respective component of circuitry of the first plurality of I/O blocks and output a voltage to the respective component based on the regulator phase, a second integrated circuit including a second plurality of I/O blocks and a second plurality of voltage regulators, wherein respective I/O blocks of the second plurality of I/O blocks include a voltage regulator of the second plurality of voltage regulators, and wherein each voltage regulator of the first plurality of voltage regulators is configured to control a regulator phase of a plurality of regulatory phases of each voltage regulator to operate based on a configuration of a respective component of circuitry of the second plurality of I/O blocks and output a voltage to the respective component based on the regulator phase, and one power rail to provide a voltage to the first plurality of voltage regulators and the second plurality of voltage regulators.

EXAMPLE EMBODIMENT 17. The multi-die package of example embodiment 16, wherein the first plurality of I/O blocks support communications using a first protocol and configurable to support communications using a second protocol different from the first protocol, and wherein the first plurality of voltage regulators is configurable to provide voltage at a second voltage level usable by the first plurality of I/O blocks when supporting the communications using the second protocol.

EXAMPLE EMBODIMENT 18. The multi-die package of example embodiment 16, wherein a first voltage regulator of the first plurality of voltage regulators is to output a first voltage usable by a first I/O block of the first plurality of I/O blocks, and wherein a second voltage regulator of the second plurality of voltage regulators is to output a second voltage usable by a second I/O block of the first plurality of I/O blocks, wherein the first voltage is different from the second voltage.

EXAMPLE EMBODIMENT 19. The multi-die package of example embodiment 16, wherein the first integrated circuit includes a secure device manager, and wherein the secure device manager includes a respective voltage regulator of the first plurality of voltage regulators.

EXAMPLE EMBODIMENT 20. The multi-die package of example embodiment 16, wherein the first integrated circuit includes a hardened accelerator, and wherein the hardened accelerator includes a respective voltage regulator of the first plurality of voltage regulators.

1. An integrated circuit, comprising:
a plurality of input/output (I/O) blocks; and
a plurality of integrated voltage regulators, wherein an I/O block of the plurality of I/O blocks comprises a voltage regulator of the plurality of integrated voltage regulators, and wherein the voltage regulator is to:
adjust a regulator voltage outputted by the voltage regulator based on a configuration of the I/O block.

2. The integrated circuit of claim 1, wherein the voltage regulator is to vary a number of enabled regulator phases based on the configuration of the I/O block.

3. The integrated circuit of claim 2, comprising one power rail communicatively coupled to the plurality of integrated voltage regulators, wherein each voltage regulator of the plurality of integrated voltage regulators is to:
receive a voltage only from the one power rail;
generate the regulator voltage by adjusting the voltage to a target voltage level usable by the I/O block based on the configuration of the I/O block; and
output the regulator voltage to the I/O block.

4. The integrated circuit of claim 1, wherein the I/O block is to support a first device operating at a first target voltage level and a second I/O block of the plurality of I/O blocks is to support a second device operating at a second target voltage level.

5. The integrated circuit of claim 4, wherein the second I/O block comprises a second voltage regulator of the plurality of integrated voltage regulators, wherein the second voltage regulator is to output a second regulator voltage at the second target voltage level different from the first target voltage level.

6. The integrated circuit of claim 1, comprising:
a plurality of sectors of programmable logic circuitry positioned proximate to the plurality of I/O blocks; and
a plurality of additional voltage regulators, wherein the plurality of additional voltage regulators is to provide an additional regulator voltage to the plurality of sectors of programmable logic circuitry.

7. The integrated circuit of claim 6, wherein a first additional voltage regulator of the plurality of additional voltage regulators is to provide a first additional regulator voltage to a first sector of the plurality of sectors of programmable logic circuitry based on a first configuration of the first sector and a second additional regulator voltage to a second sector of the plurality of sectors of programmable logic circuitry based on a second configuration of the second sector.

8. The integrated circuit of claim 1, wherein the voltage regulator is to:
receive an indication of an additional configuration of the I/O block, wherein the indication comprises a configuration bitstream to be implemented by the I/O block; and
vary the regulator voltage outputted by the voltage regulator based on the indication by varying a number of enabled regulator phases.

9. An integrated circuit, comprising:
one power rail to provide a voltage; and
a first voltage regulator coupled to the one power rail to:
receive the voltage;
adjust, via a first number of regulator phases, the voltage to a first voltage level usable by a first I/O block of a plurality of I/O blocks to support communications using a first protocol based on a first configuration of the first I/O block; and
provide the first voltage level to the first I/O block, wherein the first voltage regulator is disposed within the first I/O block.

10. The integrated circuit of claim 9, comprising:
a second voltage regulator coupled to the one power rail, the second voltage regulator to:
receive the voltage;
adjust, via a second number of regulator phases, the voltage to a second voltage level usable by a second I/O block of the plurality of I/O blocks to support communications using a second protocol based on a second configuration of the second I/O block; and
provide the voltage to the second I/O block, wherein the second voltage regulator is disposed within the second I/O block.

11. The integrated circuit of claim 10, wherein the first voltage level and the second voltage level are different.

12. The integrated circuit of claim 10, and wherein the first voltage level and the second voltage level are the same.

13. The integrated circuit of claim 9, wherein the first I/O block is to support communications using the first protocol and configurable to support communications using a second protocol different from the first protocol, and wherein the first voltage regulator is configurable to provide voltage at a second voltage level usable by the first I/O block when supporting the communications using the second protocol.

14. The integrated circuit of claim 9, wherein the first I/O block comprises programmable I/O blocks.

15. The integrated circuit of claim 9, wherein the first voltage regulator is to provide the first voltage level to a second I/O block of the plurality of I/O blocks.

16. A multi-die package, comprising:
a first integrated circuit comprising:
a first plurality of input/output (I/O) blocks; and
a first plurality of integrated voltage regulators, wherein a first I/O block of the first plurality of I/O blocks comprises a first voltage regulator of the first plurality of integrated voltage regulators, and wherein the first voltage regulator of the first plurality of integrated voltage regulators is to:
adjust a first regulator voltage outputted by the first voltage regulator based on a first configuration of the first I/O block; and
output the first regulator voltage to the first I/O block;
a second integrated circuit comprising:
a second plurality of I/O blocks; and
a second plurality of integrated voltage regulators, wherein a second I/O block of the second plurality of I/O blocks comprises a voltage regulator of the second plurality of integrated voltage regulators, and wherein a second voltage regulator of the second plurality of integrated voltage regulators is to:
adjust a first regulator voltage outputted by the second voltage regulator based on a second configuration of the second I/O block; and
output the second regulator voltage to the second I/O block; and
one power rail to provide a voltage to the first plurality of integrated voltage regulators and the second plurality of integrated voltage regulators.

17. The multi-die package of claim 16, wherein the first plurality of I/O blocks support communications using a first protocol and configurable to support communications using a second protocol different from the first protocol, and wherein the first plurality of integrated voltage regulators is configurable to provide a second regulator voltage at a second voltage level usable by the first plurality of I/O blocks when supporting the communications using the second protocol.

18. The multi-die package of claim 16, wherein the first regulator voltage is different from the second regulator voltage.

19. The multi-die package of claim 16, wherein the first integrated circuit comprises a secure device manager, and wherein the secure device manager comprises a second voltage regulator of the first plurality of integrated voltage regulators.

20. The multi-die package of claim 16, wherein the first integrated circuit comprises a hardened accelerator, and wherein the hardened accelerator comprises a second voltage regulator of the first plurality of integrated voltage regulators.
